(19) United States
(12) Patent Application Publication
(10) Pub. No.: US 2015/0380668 A1
(43) Pub. Date: Dec. 31, 2015

(54) ORGANIC ELECTRONIC DEVICES

(71) Applicant: AGENCY FOR SCIENCE, TECHNOLOGY AND RESEARCH, Singapore (SG)

(72) Inventors: Xizu Wang, Singapore (SG); Zhikuan Chen, Singapore (SG); Siew Lay Lim, Singapore (SG)

(21) Appl. No.: 14/758,088

(22) PCT Filed: Dec. 26, 2013
(86) PCT No.: PCT/SG2013/000551

§ 371 Date: Jun. 26, 2015

(30) Foreign Application Priority Data
Dec. 26, 2012 (SG) 201209548-5

(51) Int. Cl. H01L 51/42; H01L 51/44

(52) U.S. Cl. CPC H01L 51/4253; H01L 51/442; H01L 2251/308

(57) ABSTRACT

The present invention provides a product and manufacturing method for an organic electronic device. The electronic device comprises a first conductive layer and a second conductive layer, an organic layer disposed between said first and second conductive layer and an amphiphilic layer disposed between said organic layer and the second conductive layer.

### TECHNICAL FIELD

The present invention generally relates to an organic electronic device with an amphiphilic layer. The present invention also relates to a method of fabricating such a device.

### BACKGROUND

Organic electronic devices such as organic photovoltaic devices (OPVs), organic light-emitting diodes (OLEDs), and organic thin film transistors (OTFTs) utilize electrically conductive organic polymers and small molecules. These devices present advantages over conventional inorganic electronic devices because they are lighter, more flexible and more cost-efficient. In these devices, organic layers present may comprise of multiple polymers and organic molecules that are often used as electron donors and acceptors. Many of the high performance polymers used in these devices generally show different structural order from existing commercial polymers. These high performance polymers may also exhibit lifetime issues and degradation pathways that are quite different to existing commercial polymers.

Bulk heterojunction (BHJ) organic photovoltaic (OPV) devices are one such class of electronic devices where the electron donor and acceptor may be mixed together as an interpolymer. Although the power conversion efficiency of BHJ OPV devices has increased significantly from 4 percent to 8.3 percent in the last ten years, they still suffer from short lifetimes and reliability issues due to degradation of the devices. The degradation is attributed to poor thermal stability and charge trapping at the cathode/organic layer interface which occurs due to the incompact connection structure. This degradation process leads to an initial efficiency loss termed “burn-in”, which has been shown to be primarily the result of a drop in both fill factor (FF), open-circuit voltage (V_{oc}), and to a lesser extent, the short circuit current (J_{sc}) in the first 100 hours.

The underlying mechanism causing the “burn-in” which results in a loss of approximately 25 percent of the initial efficiency is not well understood but this “burn-in” phenomenon is known to result in the real efficiency of an OPV device to be less than 80 percent of the reported value.

Subsequently, researchers have capitalized on the use of interlayers to circumvent the direct contact between the organic photoactive donor and electrodes where high densities of carrier traps and interface dipoles can hinder efficient charge collection. Although anode interlayers have shown some success, effective cathode interlayers have been difficult to achieve due to unavailability of materials that are compatible with the cathode such that problems associated with “burn-in” of the BHJ OPV devices can be overcome.

There is therefore a need to provide an organic photovoltaic device that overcomes, or at least ameliorates, one or more of the disadvantages described above.

There is also a need to provide a method for fabricating organic photovoltaic devices that overcomes, or at least ameliorates, one or more of the disadvantages described above.

### SUMMARY

In one aspect, there is provided an organic electronic device comprising:

(i) a first conductive layer and a second conductive layer;

(ii) an organic layer disposed between said first and second conductive layer; and

(iii) an amphiphilic layer disposed between said organic layer and the second conductive layer.

The organic electronic device may comprise OPV devices, organic light-emitting diodes, organic thin-film transistors, biological sensors, or chemical sensors. The first and second conductive layers may serve as the anode and cathode respectively.

Advantageously, the presence of an amphiphilic layer in such devices, disposed between the organic layer and the second conductive layer may mitigate photo-stability and thermal stability issues. The amphiphilic layer separates the organic layer from the conductive cathode metal. This may help to prevent any possible interactions between the layers that can result in the degradation of the device, particularly in the presence of light or heat. Further advantageously, the amphiphilic layer may circumvent the diminishing of the power conversion efficiency of the OPV by preventing moisture and oxygen diffusion into the interface between the organic layer and the conductive cathode metal, as well as metal diffusion from the cathode layer into the organic layer. By avoiding direct contact between the organic layer and the metal cathode, the amphiphilic layer may allow the device to circumvent high densities of carrier traps and interface dipoles that can hinder efficient charge collection.

Advantageously, the amphiphilic layer may be a monolayer. This amphiphilic monolayer may enhance the connection between the organic layer and the metal cathode not only because of the above advantage in circumventing carrier traps but also because it may act as an efficient carrier channel. Moreover, the amphiphilic monolayer may provide a more compact connecting structure that may aid the stabilization of the interface between the organic layer and the metal cathode, thereby overcoming poor thermal stability and undesired charge trapping arising from incompact connection structure.

More advantageously, the amphiphilic layer may improve the lifetime and power conversion efficiency of the organic electronic device as it mitigates the above degradation issues by preventing diffusion and reactions between the organic layer and the second conductive layer.

The provision of the amphiphilic monolayer may overcome the limitation that suitable materials compatible between the organic layer and the metal cathode are lacking, without compromising the fill factor (FF), open-circuit voltage (V_{oc}), and the short circuit current (J_{sc}) of the device.

In another aspect, there is provided a method for fabricating an organic electronic device, comprising:

(i) forming a first conductive layer;

(ii) spin coating a mixture of organic materials on said first conductive layer to form an organic layer;

(iii) inserting an amphiphilic layer between said organic layer and a second conductive layer; and

(iv) depositing said second conductive layer after, inserting said amphiphilic layer.

The provision of an amphiphilic layer in organic electronic devices, which may be a monolayer, provides the abovementioned advantages. This amphiphilic monolayer is inserted via any deposition method, e.g., spin coating, such that the monolayer is disposed between the organic layer and metal cathode in order to overcome the above issues, in particular the high densities of carrier traps and interface dipoles that can hinder efficient charge collection, incompact connection structure and to avoid any possible interactions between the organic and metal layer that may degrade the devices.

Notably, the insertion of this amphiphilia monolayer may overcome the limitation that suitable materials compatible between the organic layer and the metal cathode are lacking. Moreover, the insertion of this amphiphilic monolayer may not compromise the fill factor (FF), open-circuit voltage (V_{oc}), and the short circuit current (J_{sc}) but may improve the lifetime and power conversion efficiency of the device instead.

In another aspect, there is provided an organic electronic device fabricated according to the methods as defined above.

### DEFINITIONS

The following words and terms used herein shall have the meaning indicated:

The term “monolayer” refers to a closely packed layer of atoms or molecules. More specifically, a “monolayer” refers to a layer that is one-molecule thick. That is, the thickness of the layer is equivalent to the chain length of the molecule comprising that layer. Such a “monolayer” is illustrated in FIG. 2 of the present disclosure.

The phrase “amphiphilic molecule” refers to a single molecule comprising one hydrophilic end while the other end is hydrophobic. This means that the hydrophilic end may tend to have a higher affinity for water, or readily absorbing or dissolving in water as compared to the hydrophobic end while the hydrophobic end may tend to have a higher affinity for, tending to combine with, or capable of dissolving in non-polar solutions as compared to the hydrophilic end.

Likewise, the phrases “amphiphilic layer” and “amphiphilic monolayer” refer to a layer comprising a plurality of such “amphiphilic molecule” and should be construed in a similar Manner.

The phrase “photo-stable” refers to molecules or compositions that are not affected by the effects of light.

The phrase “thermal-stable” refers to molecules or compositions that are not affected by the effects of heat.

The phrase “small molecules” refers to non-polymeric compounds with a molecular weight of less than 900 atomic mass unit (a.m.u).

The phrase “conjugated system” refers to a chemical system of connected p-orbitals with delocalized electrons in compounds with alternating single and multiple bonds, which in general may lower the overall energy of the molecule and increase stability. The compound containing the conjugated system may be cyclic, acyclic, linear or a mixture thereof.

The term “conductive” refers to any material that allows the flow of electrons or any carriers or particles with charges (either positive or negative). The phrase “conductive layer” is to be construed accordingly.

The term “transparent” refers to the optical property of a material that may allow the transmittance of any component of the electromagnetic spectrum, particularly ultraviolet rays or visible light. This means that, for instance, visible light may pass through a “transparent material” either partially or totally. Likewise, the term “clear”, when referred to a material, for instance “clear plastic”, is to be construed in a similar manner.

On the other hand, the term “opaque” refers to the optical impenetrability of a material to any component of the electromagnetic spectrum, especially visible light. Basically, an opaque material is not transparent (does not allow all light to pass through).

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the terms “about” and “approximately”, in the context of concentrations of components of the formulations, or where applicable, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DISCLOSURE OF OPTIONAL EMBODIMENTS

Illustrative, non-limiting embodiments of an organic photovoltaic device, and the method of fabrication of such a device, will now be disclosed.

The organic electronic device comprises: (i) a first conductive layer and a second conductive layer; (ii) an organic layer disposed between said first and second conductive layer; and (iii) an amphiphilic layer disposed between said organic layer and the second conductive layer.

The organic electronic device may be an organic photovoltaic (OPV) device, organic light-emitting diodes, organic thin-film transistors, or biological and chemical sensors. The organic electronic device may be a bulk heterojunction OPV device. The organic electronic device may comprise a first conductive layer. The first conductive layer may comprise an anode. The anode may comprise an electron donor.

The organic electronic device may comprise a second conductive layer. The second conductive layer may comprise a cathode. The cathode may comprise an electron acceptor.

The electron donor and electron acceptor may comprise organic or inorganic molecules. The electron donor and electron acceptor may be organic molecules. The electron donor and electron acceptor may form a highly conjugated system. The electron donor and electron acceptor may form an interface. The electron donor and electron acceptor may be mixed together to form a blended layer comprising polymers, inorganic or organic molecules, or a combination thereof.

The organic electronic device may be a bulk heterojunction (BHJ) OPV device. The organic electronic device may comprise any of the abovementioned devices.

The first conductive layer may serve as an anode. The anode may be transparent or opaque. Advantageously, the transparent anode may allow the transmittance of light to facilitate generation of photoelectrons in the organic layer while comprising a high concentration of charge carriers. The transparent anode may comprise a transparent substrate. The transparent substrate may be a glass substrate or a clear polymer substrate with patterned metal. The clear polymer substrate may be a clear plastic. The anode may further comprise metal, a metal oxide or any conducting material which may be patterned on the substrate. The patterned metal may be a transparent conducting oxide. The patterned metal may comprise silver, graphene, indium zinc oxide, aluminium zinc oxide, gallium zinc oxide, SnO₂:F or indium tin oxide (ITO). The transparent anode may comprise a glass substrate with patterned ITO. The transparent anode may also comprise a clear plastic substrate with patterned ITO. Patterning of the anode may increase the interfacial area for charge collection. This feature may also be applied to the cathode to obtain a similar advantage. Accordingly, when the anode and cathode are overlapped with each other to form an active area, the patterned anode and/or cathode may enhance the performance of the OPV devices due to the increased interfacial area for charge collection within the active area.

Advantageously, the ITO may be a heavily-doped n-type semiconductor with a large bandgap of around 4 eV. Because of the bandgap, it may be mostly transparent in the visible part of the spectrum.

These substrates may be rigid or flexible. The choice of the substrate, whether rigid or flexible, may depend on its suitability in a particular application. Advantageously, the rigid substrate may allow a longer lifetime for the device, while the flexible substrate may allow application of the device as flexible thin films on curved surfaces or in space-limited applications. For example, when conventional transparent glass is used as the substrate, it imparts mechanical strength (rigidity) to the device as a whole. However, such a device would not be able to bend without being broken. On the other hand, if a clear plastic is used, such devices may bend sufficiently without breaking apart.

The clear plastic substrate used may have a proper permeation barrier suitable for OPV applications. Basically, this means that the clear plastic substrate may be a visible light or UV transparent substrate suitable for OPV applications.

In the present disclosure, the second conductive layer may serve as a cathode. The cathode may comprise a metal or an alloy of a metal selected from a Group 1 metal, Group 2 metal, Group 3 metal or a transition metal. The cathode may comprise a metal selected from the group consisting of Ca, Li, Ba, Mg, Al and Ag. The cathode may also comprise halogen salts of Li, Li salt alloys with Al and combinations thereof. The cathode may also comprise LiF/Al or a combination of this material with at least one of the abovementioned metals.

The device may further comprise an interface layer disposed between the transparent anode and the organic layer. Interface materials may be non-conducting, semiconducting or conducting layers. The interface layer may be made from organic or inorganic materials. This interface layer may comprise a polymer. This interface layer may also comprise a mixture of two polymers. The polymers may be ionomers. It is to be noted that the polymers used for this interface layer may be non-conducting, semiconducting or conducting. Advantageously, the interface layer may minimize the contact resistance and charge recombination and enable efficient extraction of electrons or other charged carriers. The interface layer may be a polythiophene. The interface layer may comprise poly(3,4-ethylenedioxythiophene):polystyrene sulfonic acid (PEDOT:PSS), ZnO, TiO₂, MoO₃, Al₂O₃ or LiF. The interface layer may have a thickness range of about 1 nm to about 1000 nm. The interface layer may have a thickness range of about 1 nm to about 10 nm, about 1 nm to about 20 nm, about 1 nm to about 30 nm, about 1 nm to about 40 nm, about 1 nm to about 50 nm, about 1 nm to about 100 nm, about 1 nm to about 200 nm, about 1 nm to about 500 nm, about 10 nm to about 20 nm, about 10 nm to about 30 nm, about 10 nm to about 40 nm, about 10 nm to about 50 nm, about 10 nm to about 100 nm, about 10 nm to about 200 nm, about 10 nm to about 500 nm, about 10 nm to about 1000 nm, about 20 nm to about 30 nm, about 20 nm to about 40 nm, about 20 nm to about 50 nm, about 20 nm to about 100 nm, about 20 nm to about 200 nm, about 20 nm to about 500 nm, about 20 nm to about 1000 nm, about 30 nm to about 40 nm, about 30 nm to about 50 nm, about 30 nm to about 100 nm, about 30 nm to about 200 nm, about 30 nm to about 500 nm, about 30 nm to about 1000 nm, about 40 nm to about 50 nm, about 40nm to about 100 nm, about 40 nm to about 200 nm, about 40 nm to about 500 nm, about 40 nm to about 1000 nm, about 50 nm to about 100 nm, about 50 nm to about 200 nm, about 50 nm to about 500 nm, about 50 nm to about 1000 nm, about 100 nm to about 200 nm, about 100 nm, to about 500 nm, about 100 nm to about 1000 nm, about 200 nm to about 500 nm, about 200 nm to 1000 nm or about 500 nm to about 1000 nm.

The organic layer may comprise organic polymers, organic molecules or a mixture thereof. The organic layer may comprise a first polymeric component and a second organic component, wherein the first polymeric component may be blended with the second organic component. The ratio of the two components may depend on the type of materials used for each respective component. The first polymeric component may comprise low-band gap p-type materials. The second organic component may comprise low-band gap n-type materials. The first polymeric component may comprise poly(3-hexylthiophene-2,5-diyl) (P3HT) as exemplified in the structure below;

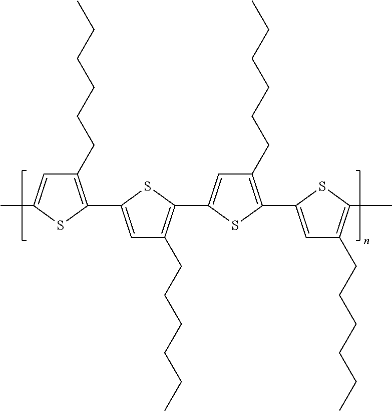

poly{(benzo-2,1,3-thiadiazol-4,7-diyl)-alt-(3′,4″-di(2-octyldodecyl)-2,2′;5′,2″;5″,2′″-quaterthiophen-5,5′″-diyl)}(PODT2T-DTBT) as exemplified in the structure below;

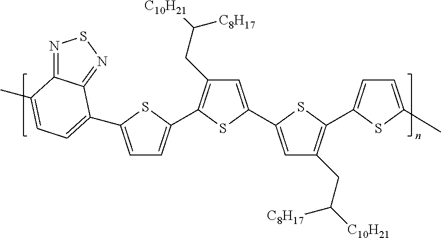

poly[2-methoxy-5-(2-ethylhexyloxy)-1,4-phenylenevinylene](MEH-PPV), poly(2-methoxy-5-(3′-7′-dimethyloctyloxy)-1,4-phenylenevinylene) (MDMO-PPV) or cyano-polyphenylene vinylene (CN-PPV) and the second organic component may comprise a fullerene. The fullerene may be a conductive fullerene. The fullerene may comprise a methano-functionalized C60 derivative. The fullerene may comprise [6,6]-phenyl C₆₁ butyric acid methyl ester (PCBM) or [6,6]-phenyl C₇₁ butyric acid methyl ester (PC₇₁BM), as exemplified in the structure below.

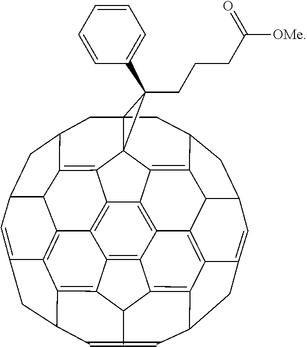

The amphiphilic layer may be disposed adjacent to the organic layer. The amphiphilic layer may be a monolayer. This amphiphilic layer may comprise a plurality of single amphiphilic molecules. The amphiphilic layer may be transparent and conducting at the nanoscale. Advantageously, this amphiphilic layer or monolayer may enhance the connection between the organic layer and the metal cathode not only because it may circumvent carrier traps but also because it may act as an efficient carrier channel. Further advantageously, the amphiphilic layer or monolayer may provide a more compact connecting structure that may aid the stabilization of the interface between the organic layer and the metal cathode, thereby overcoming poor thermal stability and undesired charge trapping arising from incompact connection structure. Even more advantageously, this layer or monolayer may also serve as an efficient carrier channel between the two layers, thereby improving charge collection. Notably, the presence of this amphiphilic layer in the disclosed organic electronic device may not compromise the fill factor (FF), open-circuit voltage (V_{oc}), and the short circuit current (J_{sc}).

The single amphiphilic molecule may comprise anionic, cationic, zwitterionic or non-ionic molecules. The single amphiphilic molecule may comprise a hydrophilic group at one end and a hydrophobic group at the other end. The single amphiphilic molecule may comprise, but are not limited to, an acid or metal salt of; stearate, oleate, dodecyl sulfate, laureate, dodecanoate, dodecyl sulfonate, dodecyl benzene sulfonate, octanoate, dodecanoate, myristate, palmitate, hexanoate, octanoate-1-¹³C, butyrate, valproate, hexanoate-(carboxy-¹⁴C), octyl sulfate, decyl sulfate, hexadecyl sulfate, dodecyl sulfate, tetradecyl sulfate, 1-octanesufonate, 1-heptanesulfonate, 1-octanesulfonate monohydrate, octadecyl suflate, dioctyl sulfosuccinate, (R)-β-hydroxyisobutyrate, acetate, deoxycholate, benzoate, deoxycholate monohydrate, ethoxide, salicylate, dodecylbenzenesulfonate, propionate, acrylate, hexanesulfonate, pentanesulfonate, decanoate, ethanetholate, phenoxide, methanesuflonate, methanesulfinate, cyclamate, xylenesulfonate or benzenesulfonate.

The single amphiphilic molecule may also comprise, but are not limited to, biological amphiphilic compounds such as phospholipids, cholesterol, glycolipids, fatty acids, bile acids, saponins or any other forms of lipids.

The counter-ion for the single amphiphilic molecule may be hydrogen, a group 1 metal or a group 2 metal. The counter-ion for the single amphiphilic molecule may comprise, but are not limited to; H, Li, Na, K, Rb, Sr, Mg or Ca.

The single amphiphilic molecule may comprise sodium stearate, as exemplified by the structure below;

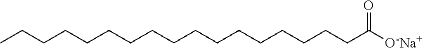

or sodium oleate, as exemplified by the structure below.

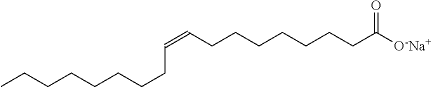

The thickness of the amphiphilic layer may depend on the type of amphiphilic molecule. The thickness of the amphiphilic layer may depend on the chain length of the molecule. Exemplary thicknesses may be in the range of about 0.1 to about 10.0 nm, about 0.1 nm to about 1.0 nm, about 0.1 nm to 2.0 nm, about 0.1 nm to about 3.0 nm, about 0.1 nm to about 4.0 nm, about 0.1 nm to about 5.0 nm, about 0.1 nm to about 6.0 nm, about 0.1 nm to about 7.0 nm, about 0.1 nm to about 8.0 nm, about 0.1 nm to about 9.0 nm, about 1 nm to 2.0 nm, about 1 nm to about 3.0 nm, about 1.0 nm to about 4.0 nm, about 1.0 nm to about 5.0 nm, about 1.0 nm to about 6.0 nm, about 1.0 nm to about 7.0 nm, about 1.0 nm to about 8.0 nm, about 1.0 nm to about 9.0 nm, about 1.0 nm to about 10.0 nm, about 2.0 nm to about 3.0 nm, about 2.0 nm to about 4.0 nm, about 2.0 nm to about 5.0 nm, about 2.0 nm to about 6.0 nm, about 2.0 nm to about 7.0 nm, about 2.0 nm to about 8.0 nm, about 2.0 nm to about 9.0 nm, about 2.0 nm to about 10.0 nm, about 3.0 nm to about 4.0 nm, about 3.0 nm to about 5.0 nm, about 3.0 nm to about 6.0 nm, about 3.0 nm to about 7.0 nm, about 3.0 nm to about 8.0 nm, about 3.0 nm to about 9.0 nm, about 3.0 nm to about 10.0 nm, about 4.0 nm to about 5.0 nm, about 4.0 nm to about 6.0 nm, about 4.0 nm to about 7.0 nm, about 4.0 nm to about 8.0 nm, about 4.0 nm to about 9.0 nm, about 4.0 nm to about 10.0 nm, about 5.0 nm to about 6.0 nm, about 5.0 nm to about 7.0 nm, about 5.0 nm to about 8.0 nm, about 5.0 nm to about 9.0 nm, about 5.0 nm to about 10.0 nm, about 6.0 nm to about 7.0 nm, about 6.0 nm to about 8.0 nm, about 6.0 nm to about 9.0 nm, about 6.0 nm to about 10.0 nm, about 7.0 nm to about 8.0 nm, about 7.0 nm to about 9.0 nm, about 7.0 nm to about 10.0 nm, about 8.0 nm to about 9.0 nm, about 8.0 nm to about 10.0 nm or about 9.0 nm to about 10.0 nm. It is to be noted as defined above, the amphiphilic layer may be an amphiphilic monolayer if the layer thickness is equivalent to the molecular chain length of the amphiphilic molecules used.

The amphiphilic monolayer may have a thickness of about 1.0 nm, 2.0 nm, 3.0 nm, 4.0 nm, 5.0 nm, 6.0 nm, 7.0 nm, 8.0 nm, 9.0 nm or 10.0 nm. It is to be appreciated that the above ranges or specific values are not particularly limited and can be adjusted as desired. Advantageously, the thickness of the amphiphilic layer may be chosen to obtain optimized efficiency and prevent possible complications due to ion motion and concominant redistribution of internal electric fields in the device. The thickness of the amphiphilic layer or monolayer may also be the chain length of the amphiphilic molecule. If sodium stearate or sodium oleate is used as the amphiphilic molecule in the amphiphilic monolayer, then the monolayer may have a thickness of about 2.0 nm. Advantageously, when the thickness of the amphiphilic monolayer coincides with the chain length of the molecule, the carriers may possess improved mobility at single molecular chain length which aids the transfer of charges to the second conductive cathode. For sodium stearate and sodium oleate, an amphiphilic layer thickness of 1 nm or 5 nm, that is a non-optimal layer thickness, may result in a decrease in the power conversion efficiency.

The organic electronic device may be encapsulated before removal into ambient atmosphere. The encapsulation may be done with a barrier material. The organic electronic device may be fabricated on a glass substrate and encapsulated with a glass lid in a glove box, sealed with a sealant. The sealant may be cured via ultraviolet irradiation for four minutes.

A method for fabricating an organic electronic device may comprise the steps of: (i) forming a first conductive layer; (ii) spin coating a mixture of polymers on said first conductive layer to form an organic layer; (iii) inserting an amphiphilic monolayer between said organic layer and a second conductive layer; and (iv) depositing said second conductive layer after inserting said amphiphilic layer.

The method may be used to fabricate an organic electronic device that is a bulk heterojunction organic photovoltaic (OPV) device. The method may be used to fabricate other organic electronic device such as organic light-emitting diodes, organic thin-film transistors, or biological and chemical sensors.

The method may comprise the step of forming a first conductive layer which may serve as the anode. This anode formed may be transparent. This anode formed may comprise a glass substrate with patterned ITO. The method for patterning a glass substrate with ITO to form said transparent anode may be to deposit ITO onto polished soda lime float glass, and subsequently depositing a SiO₂ barrier coating between the ITO and the glass. Thin films of ITO may be deposited on surfaces by physical vapor deposition. Physical vapor deposition may comprise electron beam evaporation or a range of sputter deposition techniques. The anode formed in the above method may comprise a clear plastic substrate, instead of glass, patterned with ITO. The anode formed may further comprise metal, a metal oxide or any conducting material which may be patterned on the substrate. The patterned metal used may comprise silver, graphene, indium zinc oxide, aluminium zinc oxide, gallium zinc oxide, SnO₂:F or indium tin oxide (ITO). Patterning of the anode may increase the interfacial area for charge collection. This feature may also be applied to the cathode to obtain a similar advantage. Accordingly, when the anode and cathode are overlapped with each other to form an active area, the patterned anode and/or cathode may enhance the performance of the OPV devices due to the increased interfacial area for charge collection within the active area.

The substrate used in the above method may be rigid or flexible, with the choice of substrate depending on its suitability for the particular application. Advantageously, the rigid substrate may allow a longer lifetime for the device, while the flexible substrate may allow application of the device as flexible thin films on curved surfaces or in space-limited applications. As illustrated above, when conventional transparent glass is used as the substrate, it imparts mechanical strength (rigidity) to the device as a whole. However, such a device would not be able to bend without being broken. On the other hand, if a clear plastic is used, such devices may bend sufficiently without breaking apart.

The clear plastic substrate used in the above method may have a proper permeation barrier suitable for OPV applications. Basically, this means that the clear plastic substrate may be a visible light or UV transparent substrate suitable for OPV applications.

The method may further comprise depositing an interface layer onto the transparent anode by spin coating. The interface materials used in this method may be non-conducting, semiconducting or conducting layers. These materials may be organic or inorganic. This interface layer may comprise a polymer. This interface layer may also comprise a mixture of two polymers. The polymers may be ionomers. It is to be noted that the polymers used for this interface layer may be non-conducting, semiconducting or conducting. This interface layer may also comprise PEDOT:PSS (poly(3,4-ethylenedioxythiophene):polystyrene sulfonic acid), ZnO, TiO₂, MoO₃, Al2O₃ or LiF. The spin coating may be carried out by applying components of the layer onto the center of the substrate (with or without the anode material or ITO already formed on the substrate), which may be spinning at low speed or not spinning at all. The substrate may then be rotated at high speed in order to spread the interface material by centrifugal force. The interface layer deposited may have a thickness in the range of about 1 nm to about 1000 nm. The interface layer may have a thickness range of about 1 nm to about 10 nm, about 1 nm to about 20 nm, about 1 nm to about 30 nm, about 1 nm to about 40 nm, about 1 nm to about 50 nm, about 1 nm to about 100 nm, about 1 nm to about 200 nm, about 1 nm to about 500 nm, about 10 nm to about 20 nm, about 10 nm to about 30 nm, about 10 nm to about 40 nm, about 10 nm to about 50 nm, about 10 nm to about 100 nm, about 10 nm to about 200 nm, about 10 nm to about 500 nm, about 10 nm to about 1000 nm, about 20 nm to about 30 nm, about 20 nm to about 40 nm, about 20 nm to about 50 nm, about 20 nm to about 100 nm, about 20 nm to about 200 nm, about 20 nm to about 500 nm, about 20 nm to about 1000 nm, about 30 nm to about 40 nm, about 30 nm to about 50 nm, about 30 nm to about 100 nm, about 30 nm to about 200 nm, about 30 nm to about 500 nm, about 30 nm to about 1000 nm, about 40 nm to about 50 nm, about 40 nm to about 100 nm, about 40 nm to about 200 nm, about 40 nm to about 500 nm, about 40 nm to about 1000 nm, about 50 nm to about 100 nm, about 50 nm to about 200 nm, about 50 nm to about 500 nm, about 50 nm to about 1000 nm, about 100 nm to about 200 nm, about 100 nm, to about 500 nm, about 100 nm, to about 1000 nm, about 200 nm to about 500 nm, about 200 nm to 1000 nm or about 500 nm to about 1000 nm. The thickness of the interlayer may be achieved by spin coating at a specific rotational speed.

The method may comprise depositing an organic layer on the above interface layer by spin coating. The organic layer may comprise organic polymers, organic molecules or a mixture thereof. This organic layer may be a bulk heterojunction blend. The bulk heterojunction blend may comprise a first polymeric component and a second organic component, wherein the first and second components may be mixed in a dissolution agent before spin coating. The ratio of the two components may depend on the type of materials used for each respective component. The first polymeric component may comprise low-band gap p-type materials. The second organic component may comprise low-band gap n-type materials. The heterojunction blend may be formed by mixing a first polymeric component comprising poly(3-hexylthiophene-2,5-diyl) (P3HT) poly{(benzo-2,1,3-thiadiazol-4,7-diyl)-alt-(3′,4″-di(2-octyldodecyl)-2,2′;5′,2″;5″,2′″-quaterthiophen-5,5′″-diyl)}(POD2T-DTBT), poly[2-methoxy-5-(2-ethylhexyloxy)-1,4-phenylenevinylene](MEH-PPV), poly(2-methoxy-5-(3′-7′-dimethyloctyloxy)-1,4-phenylenevinylene) (MDMO-PPV) or cyano-polyphenylene vinylene (CN-PPV) with a second organic component comprising conductive fullerenes such as [6,6]-phenyl C₆₁ butyric acid methyl ester (PCBM) or [6,6]-phenyl C₇₁ butyric acid methyl ester (PC₇₁BM), dissolved in 1,2-dichlorobenzene.

The method may comprise inserting an amphiphilic layer which may be deposited onto the organic layer via a physical, chemical or solution deposition process. This amphiphilic layer may be a monolayer. Advantageously, this insertion of an amphiphilic layer or monolayer may enhance the connection between the organic layer and the metal cathode not only because of the above advantage in circumventing carrier traps but also because it may act as an efficient carrier channel. More advantageously, the amphiphilic layer or monolayer may provide a more compact connecting structure that aids the stabilization of the interface between the organic layer and the metal cathode, thereby overcoming poor thermal stability and undesired charge trapping arising from incompact connection structure. The amphiphilic layer or monolayer may form the compact connecting structure between the two different materials of the organic layer and the metal cathode by possessing a hydrophobic moiety that has high affinity for the organic layer and a hydrophilic moiety that has high affinity for the metal cathode.

The deposition of the amphiphilic layer or monolayer may be carried out by thin film deposition. This thin film deposition method may comprise thermal evaporation or solution processes. The thin film deposition may comprise thermal evaporation, spin coating, spray coating, screen printing, blade coating or any of their combination thereof. It is to be noted that any other deposition methods known to the skilled person may be used as long as it fulfills the function of depositing the amphiphilic layer onto the organic layer. Advantageously, the deposition of the amphiphilic layer on the organic layer may allow the formation of a monolayer of amphiphilic molecules which may separate the organic layer from the cathode. This may prevent atomic diffusion and reactions between the organic layer and the metal cathode. By using said thin film deposition techniques, deposition of a thin layer of desired amphiphilic layer or monolayer may be achieved.

The amphiphilic layer or monolayer may be deposited onto the organic layer by thermal evaporation. This thermal evaporation method may be carried out by heating an organic material in vacuum. The vacuum may be created in a vacuum chamber. The substrate may be placed several centimeters away from the source such that the evaporated material may be directly deposited onto the substrate. Advantageously, this method of thermal evaporation may be a physical deposition process that may allow deposition of many layers of different materials without any chemical interactions between the different layers.

The amphiphilic layer or monolayer may be deposited onto the organic layer by spin coating. The amphiphilic layer may be formed by spin rotation at a range of about 500 to about 5000 rpm at room temperature.

The amphiphilic layer may also be deposited onto the organic layer by screen printing or blade coating.

The amphiphilic monolayer deposited onto the organic layer may comprise a plurality of single amphiphilic molecules disposed between the organic layer and the cathode metal which may be subsequently deposited. The single amphiphilic molecule may be selected from, but are not limited to, the group consisting of an acid or metal salt of stearate, oleate, dodecyl sulfate, laureate, dodecanoate, dodecyl sulfonate, dodecyl benzene sulfonate, octanoate, dodecanoate, myristate, palmitate, hexanoate, octanoate-1-¹³C, butyrate, valproate, hexanoate-(carboxy-¹⁴C), octyl sulfate, decyl sulfate, hexadecyl sulfate, dodecyl sulfate, tetradecyl sulfate, 1-octanesufonate, 1-heptanesulfonate, 1-octanesulfonate monohydrate, octadecyl suflate, dioctyl sulfosuccinate, (R)-β-hydroxyisobutyrate, acetate, deoxycholate, benzoate, deoxycholate monohydrate, ethoxide, salicylate, dodecylbenzenesulfonate, propionate, acrylate, hexanesulfonate, pentanesulfonate, decanoate, ethanetholate, phenoxide, methanesuflonate, methanesulfinate, cyclamate, xylenesulfonate and benzenesulfonate. The amphiphilic molecules used may comprise any of the abovementioned substance.

The counter-ion for the single amphiphilic molecule may be selected from hydrogen, a group 1 or group 2 metal. The counter-ion for the single amphiphilic molecule may be selected from, but are not limited to; H, Li, Na, K, Rb, Sr, Mg or Ca.

Sodium stearate or sodium oleate may be used as the amphiphilic molecule for deposition onto the organic layer.

According to the method of the present disclosure, varying amounts of the amphiphilic molecules may be deposited on the organic layer to form an amphiphilic layer that may have a thickness in the range of about 0.1 to about 10.0 nm. This layer deposited may be form a monolayer. The amphiphilic layer may be deposited at a thickness that may depend on the type of amphiphilic molecule. The amphiphilic layer may be deposited at a thickness that may depend on the chain length of the molecule. The thickness of the amphiphilic layer may be controlled by varying the evaporation time during thermal evaporation or by varying the concentration and coating conditions during solution processes. The deposition rate may be 0.1 to 1 Å/s. The thickness of the amphiphilic monolayer may be controlled by varying the evaporation time during thermal evaporation. Exemplary thicknesses at which the amphiphilic layer may be deposited may be selected from the range of about 0.1 to about 10.0 nm, about 0.1 nm to about 1.0 nm, about 0.1 nm to 2.0 nm, about 0.1 nm to about 3.0 nm, about 0.1 nm to about 4.0 nm, about 0.1 nm to about 5.0 nm, about 0.1 nm to about 6.0 nm, about 0.1 nm to about 7.0 nm, about 0.1 nm to about 8.0 nm, about 0.1 nm to about 9.0 nm, about 1 nm to 2.0 nm, about 1 nm to about 3.0 nm, about 1.0 nm to about 4.0 nm, about 1.0 nm to about 5.0 nm, about 1.0 nm to about 6.0 nm, about 1.0 nm to about 7.0 nm, about 1.0 nm to about 8.0 nm, about 1.0 nm to about 9.0 nm, about 1.0 nm to about 10.0 nm, about 2.0 nm to about 3.0 nm, about 2.0 nm to about 4.0 nm, about 2.0 nm to about 5.0 nm, about 2.0 nm to about 6.0 nm, about 2.0 nm to about 7.0 nm, about 2.0 nm to about 8.0 nm, about 2.0 nm to about 9.0 nm, about 2.0 nm to about 10.0 nm, about 3.0 nm to about 4.0 nm, about 3.0 nm to about 5.0 nm, about 3.0 nm to about 6.0 nm, about 3.0 nm to about 7.0 nm, about 3.0 nm to about 8.0 nm, about 3.0 nm to about 9.0 nm, about 3.0 nm to about 10.0 nm, about 4.0 nm to about 5.0 nm, about 4.0 nm to about 6.0 nm, about 4.0 nm to about 7.0 nm, about 4.0 nm to about 8.0 nm, about 4.0 nm to about 9.0 nm, about 4.0 nm to about 10.0 nm, about 5.0 nm to about 6.0 nm, about 5.0 nm to about 7.0 nm, about 5.0 nm to about 8.0 nm, about 5.0 nm to about 9.0 nm, about 5.0 nm to about 10.0 nm, about 6.0 nm to about 7.0 nm, about 6.0 nm to about 8.0 nm, about 6.0 nm to about 9.0 nm, about 6.0 nm to about 10.0 nm, about 7.0 nm to about 8.0 nm, about 7.0 nm to about 9.0 nm, about 7.0 nm to about 10.0 nm, about 8.0 nm to about 9.0 nm, about 8.0 nm to about 10.0 nm or about 9.0 nm to about 10.0 nm.

The amphiphilic layer or monolayer may be deposited at a thickness of about 1.0 nm, 2.0 nm, 3.0 nm, 4.0 nm, 5.0 nm, 6.0 nm, 7.0 nm, 8.0 nm, 9.0 nm or 10.0 nm. If sodium stearate or sodium oleate is the amphiphilic molecule being used, in the amphiphilic layer, the amphiphilic monolayer may be deposited at a thickness of 2.0 nm. The thickness of the amphiphilic layer or monolayer may be controlled by changing the amount of amphiphillic molecule being deposited during the deposition process. Advantageously, this thickness may have the optimized efficiency and prevent possible complications due to ion motion and concominant redistribution of internal electric fields in the device. This thickness may also be the chain length of the amphiphilic molecule. When the thickness of the amphiphilic monolayer deposited coincides with the chain length of the molecule, the carriers may possess improved mobility at single molecular chain length which aids the transfer of charges to the second conductive cathode. For sodium stearate and sodium oleate, an amphiphilic layer deposited with a thickness of 1 nm or 5 nm, which is a non-optimal layer thickness, may result in a decrease in the power conversion efficiency.

Subsequently, the method may comprise depositing a second conductive layer onto the amphiphilic layer or monolayer which may serve as a cathode. This may be carried out by spin coating, thermal evaporation or any other deposition methods known to the skilled person as long as the cathode can be deposited onto the amphiphilic layer or monolayer. The cathode deposited may comprise a metal or an alloy of a metal selected from group 1, group 2, group 3 or transition metals. The cathode deposited may be selected from the group consisting of Ca, Li, Ba, Mg, Al and Ag. The cathode deposited may also comprise halogen salts of Li, Li salt alloys with Al and combinations thereof. The cathode may also comprise LiF/Al or a combination of this material with at least one of the abovementioned metals.

The device may be encapsulated before removal into ambient atmosphere by a process known to a person skilled in the art. The encapsulation may protect the device from air and moisture which may contribute to the degradation of the device. The organic electronic device may be fabricated on a glass substrate and encapsulated with a glass lid in a glove box with both oxygen and moisture levels that may be less than 1 ppm. The sealant used to encapsulate the organic electronic device may be cured by irradiation with UV-light for 4 minutes.

There is provided an organic electronic device fabricated according to the methods described above. Such organic electronic device may possess the above technical advantages over conventional organic electronic devices as it comprises the amphiphilic monolayer.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1a is a schematic diagram showing the structure of an organic photovoltaic device without the amphiphilic monolayer.

FIG. 1b is a schematic diagram showing the structure of an organic photovoltaic device with the amphiphilic monolayer inserted.

FIG. 2 is a schematic diagram depicting the interface between the organic layer and Nast amphiphilic monolayer.

FIG. 3a is a graph depicting the current density-voltage (J-V) characteristics of P3HT:PC₇₁BM devices with and without the sodium stearate and sodium oleate amphiphilic monolayer before and after annealing.

FIG. 3b is a graph depicting the J-V characteristics of POD2T-DTBT:PC₇₁BM devices with and without the sodium stearate amphiphilic monolayer before and after annealing.

FIG. 4a is a graph depicting a plot of the efficiency decay (normalized power conversion efficiency (PCE) against time) for P3HT:PC₇₁BM devices. The curves are each normalized by the initial value at the start of the aging process. Each point represents the average data for four devices of each type. The error bars show the highest and lowest values at each point.

FIG. 4b is a graph depicting a plot of the efficiency decay (normalized power conversion efficiency (PCE) against time) for POD2T-DTBT:PC₇₁BM devices. The curves are each normalized by the initial value at the start of the aging process. Each point represents the average data for four devices of each type. The error bars show the highest and lowest values at each point.

### DETAILED DESCRIPTION OF DRAWINGS

FIG. 1a is a schematic diagram showing the structure of an organic photovoltaic device 100 without the amphiphilic monolayer 9. The bottom most layer comprises the transparent anode 1 which is made up of a glass substrate with patterned indium tin oxide (ITO) (both are shown as a combined layer 1). The organic electronic device 100 also comprises an interface layer 3 which may be a 30.0 nm thick PEDOT:PSS (poly(3,4-ethylenedioxythiophene):polystyrene sulfonic acid) layer disposed adjacent to the transparent anode 1. The device 100 further comprises an organic layer 5 which may be made up of a bulk heterojunction blend dissolved in 1,2-dichlorobenzene solution deposited onto the interface layer 3. This bulk heterojunction blend comprises a first polymeric component selected from either P3HT or POD2T-DTBT, and a second organic component comprising PC₇₁BM. For a normal organic photovoltaic device 100 without the amphiphilic monolayer 9, the cathode 7 is deposited onto the organic layer 5.

As for an organic photovoltaic device 110 with the amphiphilic monolayer 9 as represented by. FIG. 1b, the structure is basically the same as described above except that the amphiphilic monolayer 9 is deposited onto the organic layer 5 before depositing the cathode 7. Deposition of the monolayer 9 may be carried out via spin coating, thermal evaporation or a solution process.

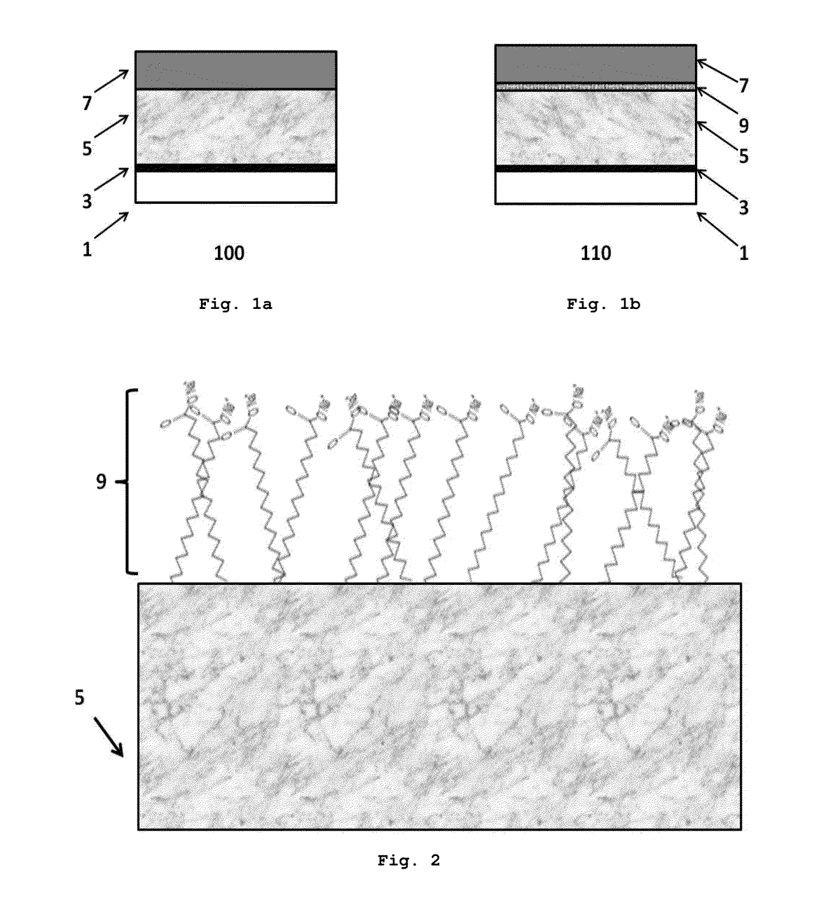

FIG. 2 is a schematic diagram depicting the interface between the organic layer 5 and the amphiphilic monolayer 9. As depicted in FIG. 2, the amphiphilic monolayer 9 is comprised of sodium stearate molecules. When the monolayer 9 is deposited, the hydrophobic end of the sodium stearate molecules is attached to the organic layer 5 while the other hydrophilic end which comprises the sodium salt of a carboxylate group will come into contact with the subsequently deposited cathode (not shown in this figure).

### EXAMPLES

Non-limiting examples of the invention will be further described in greater detail by reference to specific Examples, which should not be construed as in any way limiting the scope of the invention.

### Example 1

### Preparation of Organic Photovoltaic (OPV) Devices

To examine the amphiphilic function, two different molecules, sodium stearate and sodium oleate, were used. Devices were fabricated by spin coating the bulk heterojunction blend (BHJ) from a 1,2-dichlorobenzene solution atop a 30.0 nm thick PEDOT:PSS (poly(3,4-ethylenedioxythiophene):polystyrene sulfonic acid) layer on glass substrates with patterned indium tin oxide (ITO).

The organic layer of the fabricated devices comprised of two different BHJ blends. One BHJ blend comprised P3HT with PC₇₁BM while the other comprised POD2T-DTBT with PC₇₁BM. An example of a device comprising POD2T-DTBT with PC₇₁BM may have the following layer compositions and thicknesses:

Normal Device without Amphiphilic Layer
ITO/PEDOT:PSS—25 nm to 40 nm
POD2T-DTBT:PC₇₁BM—200 nm
Al—100 nm

Subsequently, a 2.0 nm amphiphilic monolayer was either deposited by thermal evaporation or a solution process on the organic layer. An example of a device comprising POD2T-DTBT, PC₇₁BM and an amphiphilic monolayer may have the following layer compositions and thicknesses:

Device with Amphiphilic Monolayer
ITO/PEDOT:PSS—25 to 40 nm
POD2T-DTBT:PC₇₁BM—200 nm
Nast—2 nm
Al—100 nm.

The 2.0 nm thickness was chosen to optimize efficiency and prevent possible complications due to ion motion and concomitant redistribution of internal electric fields in the device. Notably, the carrier had improved mobility at this single molecular chain length. Moreover, the amphiphilic layer thickness coincides with the chain length of the amphiphilic molecule.

An exemplified structure of the fabricated devices with the amphiphilic monolayer, as described above, is depicted in FIGS. 1b and 2.

Meanwhile, normal devices which were fabricated in a similar manner except without the amphiphilic monolayer as exemplified above, is illustrated in FIG. 1a.

These devices were further encapsulated by standard techniques to block moisture and oxygen diffusion to avoid further degradation of the device.

Outlined below are some alternative examples of the layer compositions and thicknesses in some exemplary organic electronic devices that were fabricated, using a blend of P3HT and PC₆₀BM in place of a blend of POD2T-DTBT and PC₇₁BM as the active organic layer.

Normal Device without Amphiphilic Layer
ITO/PEDOT:PSS—25 nm to 40 nm
P3HT:PCBM—200 nm
Al—100 nm
   Device with Amphiphilic Monolayer
ITO/PEDOT:PSS—25 to 40 nm
P3HT:PCBM—200 nm
Nast—2 nm
Al—100 nm

The devices were fabricated by first performing a UV-ozone treatment of the ITO substrate on the transparent anode. Following this, a 30 nm film of PEDOT:PSS (Clevios P VP Al 4083) interface layer was spin coated on the anode and annealed in an inert atmosphere at 120° C. for 10 min.

Subsequently, a solution blend of P3HT:PCBM (1:0.8 w/w) or POD2T-DTBT:PC₇₁BM (1:1 w/w) in anhydrous o-dichlorobenzene were spin-coated on the interface layer to form the active organic layer. All spin coating processes were performed in a glove-box under a nitrogen atmosphere.

A 2 nm amphiphilic monolayer of sodium stearate was then deposited by thermal evaporation or spin coating onto the organic active layer.

Finally, 100 nm of aluminium was deposited by thermal deposition onto the amphiphilic monolayer to form the cathode.

### Example 2

### Current Density-Voltage (J-V) Characteristics of the Various Organic Photovoltaic Devices

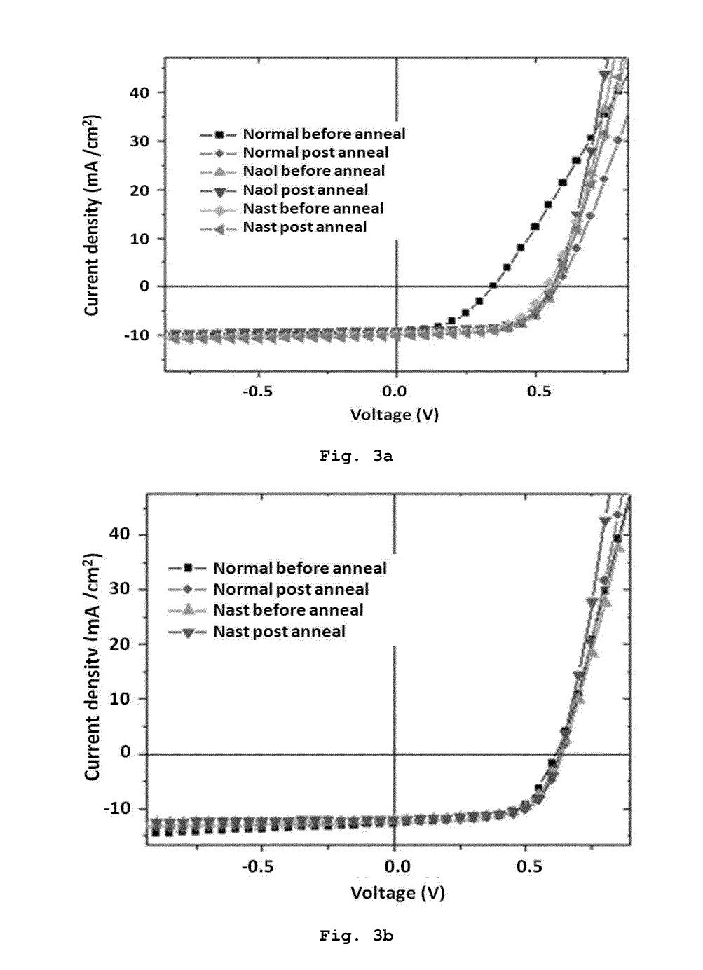

Current density-voltage (J-V) characteristics of the various devices prepared according to example 1 are shown in FIGS. 3a and 3b. J-V measurements were obtained under conditions of 100 mW/cm² of simulated AM1.5G illumination.

In FIG. 3a, the resulting J_{sc}, V_{oc}, FF, and PCE values of the OPV devices fabricated using P3HT in the organic layer, as determined from the J-V curves, were comparatively similar to normal structure devices with and without the insertion of the amphiphilic monolayer. For the, normal device, the J-V curves appear different before and after the annealing process, as the PCE increases over 80 percent. This is because the annealing process enhances the connection between the organic layer and the cathode metal, making it more compact and thereby improving the electrical performance of the device. In the devices comprising the amphiphilic monolayer, the J-V curves are very similar before and after the annealing process, only demonstrating a PCE increase of 2 percent. This is because the amphiphilic layer already provides the compact connection between the organic monolayer and the cathode metal even without annealing. In fact, the J-V values of the devices comprising the amphiphilic layer before annealing were found to be just as high as the J-V value of the normal device after annealing, suggesting that the insertion of the amphiphilic monolayer is just as effective as the annealing process.

For OPV devices based on the high performance p-type polymer POD2T-DTBT, similar observations were made from the J-V characteristics plot in FIG. 3b. A PCE increase of 10 percent was obtained from the annealed normal device, whereas the increase was only 1 to 2 percent in the device with the amphiphilic monolayer, affirming the above advantage.

As shown in FIGS. 3a and 3b, more particularly in FIG. 3a, the post-annealing process enhanced the charge connection at the organic/metal interface, thus increasing the V_{oc} and J_{sc} of the normal devices without the amphiphilic monolayer.

However, in OPV devices with the amphiphilic monolayer, the J-V characteristics were found to be as good as those of the post-annealed normal devices. These results imply that the amphiphilic monolayer not only separates the metal cathode from organic active layer, but also acts as a good carrier channel between them.

It should be further noted that for Nast and Naol, when an amphiphilic layer thickness of 1. nm or 5 nm is deposited, a decrease in the power conversion efficiency to about 10 to 20 percent resulted due to a non-optimal layer thickness.

### Example 3

### Operational lifetimes Analysis of the Various Organic Photovoltaic Devices

The samples from example 2 were then encapsulated before exposing them to ambient-atmosphere. To determine their operational lifetimes, the devices were inserted into a home-made testing chamber where they were aged under a calibrated 100 mW/cm² simulated AM1.5G illumination at 60±5° C. in open-circuit conditions. Due to the elevated testing temperature, accelerated degradation was expected. The early stages of OPV device degradation can typically be differentiated into two steps: an initial “burn-in” period characterized by exponential loss of power conversion efficiently (PCE), followed by an extended period of slow linear decay.

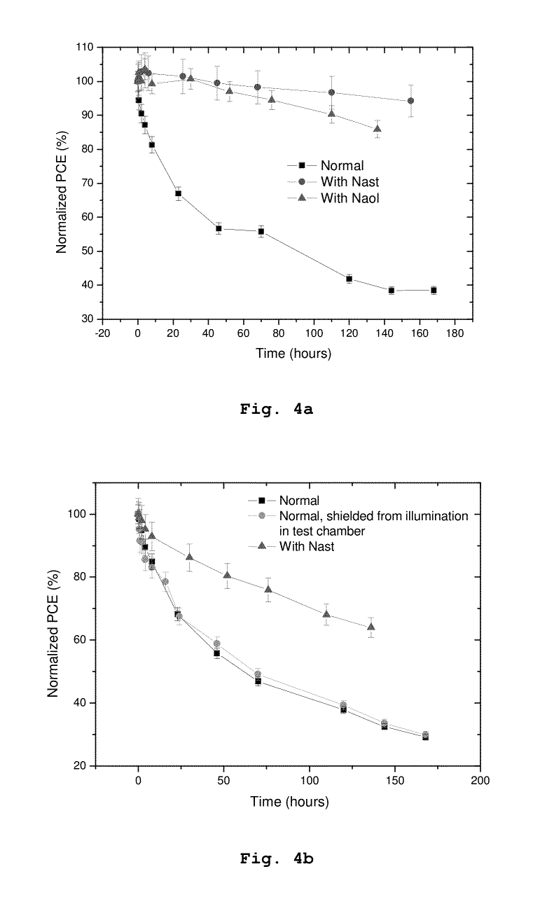

The degradation profiles (PCE against time plot) for the various devices are depicted in FIGS. 4a and 4b. The curves were normalized to their initial values at the start of the aging process and the data points represent the average value for four devices of each type of polymer used. The error bars for each point represent the maximum and minimum values for the devices at each of the data points.

“Burn-in” for the normal device without the amphiphilic monolayer was observed to be steep within the first 10 h of aging, with at least a 40% loss in PCE by the 70 h mark as observed from both FIGS. 4a and 4b.

In comparison, less PCE degradation was observed from the profiles of devices based on P3HT:PC₇₁BM or POD2T-DTBT:PC₇₁BM fabricated with the amphiphilic monolayer shown in FIGS. 4a and 4b respectively.

As shown in Table 1, compared with normal OPV devices, the operation lifetime (the definition of lifetime is the decrease in efficiency to 60% of the original value) of OPV devices with an amphiphilic monolayer were enhanced by 20 times and 4 times for P3HT:PC_{7I}BM or POD2T-DTBT:PC₇₁BM based devices respectively.

TABLE 1
Operation Lifetime of OPV Devices with and without the
Amphiphilic Monolayer

| | Lifetime of normal | Lifetime of OPV with |
|---|---|---|
| Sample | OPV | sodium stearate |
| P3HT:PC₇₁BM | 40 hrs (at 60% PCE) | ~800 hrs (at 60% PCE) |
| POD2T-DTBT:PC₇₁BM | 44 hrs (at 60% PCE) | ~180 hs (at 60% PCE) |

Comparing between P3HT:PC₇₁BM with and without the monolayer, the P3HT:PC₇₁BM devices with a 2.0 nm amphiphilic monolayer (Nast or Naol) featured significantly higher stability and longer lifetime with no obvious “burn-in” as observed from FIG. 4a.

For normal OPV devices based on POD2TDTBT:PC₇₁BM without any monolayer, the efficiency degradation under 1 sun illumination or no illumination in the test chamber exhibited similar characteristics and degradation features (also see FIG. 4b) that were less desired than the POD2T-DTBT:PC₇₁BM based devices with the monolayer. This implicitly meant that thermal decay plays a major role in the device degradation. The profile labeled Nast in FIG. 4(b) further indicates significant enhancement in the lifetime of POD2T-DTBT:PC₇₁BM device with the amphiphilic monolayer. Evidently, the nanoscale amphiphilic monolayer provided effective photo and thermal interface buffering effects in OPV devices, as explained in preceding paragraphs, thus increasing the stability and operation lifetime of OPV devices tremendously. By having the amphiphilic layer separating the organic and metal cathode interface, interactions between these layers such as atomic diffusion and other possible reactions were minimized thereby enhancing the lifetime (PCE) of the devices.

### APPLICATIONS

The disclosed organic electronic device may be more resistant to degradation than conventional organic electronic devices and may possess improved photo-stability and thermal-stability.

The disclosed organic electronic device may comprise an amphiphilic monolayer that enhances the connection and stabilization of the interface between the organic layer and the metal cathode. This amphiphilic monolayer may mitigate degradation issues by preventing layer separation as it forms a more compact connecting structure between the organic layer and the metal cathode. This monolayer may also serve as an efficient carrier channel between the two layers, thereby improving charge collection. The presence of this monolayer in the disclosed organic electronic device may not compromise the fill factor (FF), open-circuit voltage (V_{oc}), and the short circuit current (J_{sc}).

The disclosed organic electronic device may have an improved lifetime and power conversion efficiency, as well as being more resistant to the “burn-in” phenomenon.

The disclosed organic electronic device may have suitable applications as bulk heterojunction organic photovoltaic devices, organic light-emitting diodes and organic thin-film, transistors, as well as biological and chemical sensors.

The disclosed organic device may also mitigate the limitation that suitable materials compatible between the organic layer and the metal cathode are lacking.

The disclosed organic electronic device may lead to cost-savings as the organic electronic devices are cheaper to manufacture than conventional inorganic devices.

The disclosed organic electronic device may aid in the commercialization of OPV devices.

The disclosed method of fabrication for the disclosed organic electronic device may include inserting an amphiphilic layer between the organic layer and the conducting cathode.

The insertion of this amphiphilic monolayer may impart photo-stability and thermal-stability to the disclosed organic electronic device.

The disclosed method of inserting the monolayer may enhance the connection and stabilization of the interface between the organic layer and the metal cathode. The inserted amphiphilic monolayer may mitigate degradation issues by preventing layer separation as it forms a more compact connecting structure between the organic layer and the metal cathode. This inserted monolayer may also serve as an efficient carrier channel between the two layers, thereby improving charge collection.

The disclosed method may not compromise the fill factor (FF), open-circuit voltage (V_{oc}), and the short circuit current (J_{sc}).

The disclosed method may result in the disclosed organic electronic device having an improved lifetime and power conversion efficiency, as well as being more resistant to the “burn-in” phenomenon.

The disclosed method may overcome the restriction on the types of materials that are compatible between the organic layer and metal.

The disclosed method of fabrication for the disclosed organic electronic device may have useful applications in the fabrication of devices such as bulk heterojunction organic photovoltaic devices, organic light-emitting diodes and organic thin-film transistors, as well as biological and chemical sensors.

The disclosed method of fabrication may lead to cost savings as the disclosed organic electronic devices are cheaper to manufacture than conventional inorganic devices.

The disclosed method of fabrication may aid in the commercialization of OPV devices.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. An organic electronic device comprising:
(i) a first conductive layer and a second conductive layer;
(ii) an organic layer disposed between said first and second conductive layer; and
(iii) an amphiphilic layer disposed between said organic layer and the second conductive layer.

2. The device according to claim 1, wherein said organic electronic device is a bulk heterojunction organic photovoltaic (OPV) device.

3. The device according to claim 1 or 2, wherein the first conductive layer serves as an anode.

4. The device according to claim 3, wherein said anode is transparent.

5. The device according to claim 4, wherein said transparent anode comprises a transparent substrate with a transparent conducting oxide.

6. The device according to any of the preceding claims, wherein said second conductive layer serves as a cathode.

7. The device according to claim 6, wherein said cathode comprises materials selected from the group consisting of Ca, Li, Ba, Mg, Al, Ag, Ag, halogen salts of Li, Li salt alloys with Al and combinations thereof.

8. The device according to any of the preceding claims, further comprising an interface layer disposed between the first conductive layer and the organic layer.

9. The device according to any of the preceding claims, wherein said organic layer comprises a blend of a first polymeric component and a second organic component.

10. The device according to claim 9, wherein said first polymeric component comprises a conductive polymer.

11. The device according to claim 9, wherein said second organic component comprises a conductive fullerene.

12. The device according to any of the preceding claims, wherein said amphiphilid layer comprises a monolayer of amphiphilic molecules.

13. The device according to claim 12, wherein said amphiphilic monolayer has a thickness in the range of 0.1 to 10.0 nm.

14. A method for fabricating an organic electronic device, comprising:
(i) forming a first conductive layer;
(ii) coating a mixture of organic materials on said first conductive layer to form an organic layer;
(iii) inserting an amphiphilic layer between said organic layer and a second conductive layer; and
(iv) depositing said second conductive layer after inserting said amphiphilic layer.

15. The method according to claim 14, wherein said forming step (i) comprises patterning a transparent substrate with a transparent conducting oxide to form said first conductive layer.

16. The method according to claim 14 or 15, further comprising forming an interface layer on the first conductive layer.

17. The method according to claim 16, wherein said interface layer is spin-coated on said first conductive layer.

18. The method according to any one of claims 14 to 17, wherein said coating step (ii) comprises spin coating.

19. The method according to any one of claims 14 to 18, wherein said coating mixture of organic materials in step (ii) comprises a bulk heterojunction blend.

20. The method according to claim 19, wherein said heterojunction blend comprises a first polymeric component and a second organic component mixed in a dissolution agent before spin coating.

21. The method according to any one of claims 14 to 20, wherein said insertion step (iii) comprises a physical, chemical or solution deposition method to form the amphiphilic layer.

22. The method according to claim 21, wherein said deposition method comprises thermal evaporation, spin coating, screen printing, blade coating or a combination thereof.

23. The method according to any one of claims 14 to 22, wherein said depositing step (iv) comprises the deposition of material selected from the group consisting of Ca, Li, Ba, Mg, Al, Ag, halogen salts of Li, Li salt alloys with Al and combinations thereof to form the second conductive layer.

24. An organic electronic device fabricated according to the methods of claims 14 to 23.
